(19) United States
(12) Patent Application Publication
(10) Pub. No.: US 2019/0131752 A1
(43) Pub. Date: May 2, 2019

(54) ULTRASONIC WELDING DEVICE AND ULTRASONIC WELDING METHOD

(71) Applicant: HONDA MOTOR CO., LTD., Tokyo (JP)

(72) Inventors: Masaki Kunigami, Tochigi (JP); Hitoshi Saito, Tochigi (JP); Tsugio Masuda, Tochigi (JP); Nobuhiro Fueki, Tochigi (JP); Shinzo Urushidani, Tochigi (JP); Tatsuya Okunaka, Tochigi (JP); Tomoyuki Kanamaru, Tochigi (JP)

(21) Appl. No.: 16/083,568

(22) PCT Filed: Feb. 28, 2017
(86) PCT No.: PCT/JP2017/007658

§ 371 Date: Sep. 10, 2018

(30) Foreign Application Priority Data
Mar. 18, 2016 (JP) 2016-055915

(51) Int. Cl. H01R 43/02; B23K 20/10; B23K 20/26; H05K 3/36

(52) U.S. Cl. CPC H01R 43/0228; B23K 20/10; B23K 2101/42; H05K 3/361; H01R 43/0207; B23K 20/26

(57) ABSTRACT

A device capable of improving quality of welding by improving estimation precision of coating removal completion of a conductor which is an ultrasonic welding target is provided. An ultrasonic vibration energy (E) of a horn (11) is adjusted based on magnitude of a displacement amount (a reference displacement amount (ΔZ)) of the horn (11) during at least a partial period of a period from a state in which an FFC and a PCB are interposed by the horn (11) and an anvil (12), through a “first stable state” in which a displacement speed (v) of the horn (11) is stable in a first speed zone in a course in which the displacement speed (v) of the horn (11) increases, until a “second stable state” in which the displacement speed (v) is stable in a second speed zone of a higher speed zone than the first speed zone.

### TECHNICAL FIELD

The present invention relates to a technique for welding conductors to each other by ultrasonic vibration energy.

### BACKGROUND ART

Ultrasonic welding methods of welding one conductor and the other conductor coated with synthetic resins have been proposed (for example, see Patent Literatures 1 and 2). According to the ultrasonic welding methods, at least the synthetic resin with which the one conductor is coated is first melt by the ultrasonic vibration energy of a horn with a welding target interposed between the horn and an anvil, and is removed from between the both conductors. Subsequently, the both conductors are welded to each other.

A method of realizing ultrasonic welding while preventing a variation in a welding strength of the both conductors caused due to a variation in the ultrasonic vibration energy has been proposed (for example, see Patent Literature 3). According to the method, a product of a voltage applied to a vibration element vibrating the horn and a current flowing in the vibration element is calculated as a work rate given to a welding target via the horn. Then, when a rate of change in the work rate becomes equal to or less than a first predetermined value, and subsequently becomes equal to or greater than a second predetermined value greater than the first predetermined value, the coating is determined to be removed from between the conductors.

### CITATION LIST

### Patent Literature

Patent Literature 1: Japanese Patent Application Laid-Open No. 2000-263248

Patent Literature 2: Japanese Patent Application Laid-Open No. 2006-024590

Patent Literature 3: Japanese Patent No. 4456640

### SUMMARY OF INVENTION

### Technical Problem

However, since there is a transitional period in which conductor welding starts and the coating removal further progresses, there is a possibility that it is difficult to determine whether the removing of the coating is completed based on a change in the work rate. Therefore, there is a possibility that, for example, the conductor is damaged due to excessive ultrasonic vibration energy in addition to the possibility that the welding strength of the conductor is insufficient due to small ultrasonic vibration energy.

Accordingly, an object of the invention is to provide a device and the like capable of improving quality of welding by improving estimation precision of coating removal completion of conductors which are ultrasonic welding targets.

### Solution to Problem

According to an aspect of the invention, there is provided an ultrasonic welding device including: a horn that is vibrated by a piezoelectric element; an anvil that is disposed to face the horn; and a control device. A synthetic resin is melted to be removed from between one conductor and another conductor by displacing the horn in a superimposing direction of the one conductor and the other conductor while ultrasonically vibrating the horn in a state in which the one conductor and the other conductor superimposed via the synthetic resin are interposed by the horn and the anvil, and the one conductor and the other conductor are welded.

In the ultrasonic welding device according to the aspect of the invention, the control device includes a measurement element that measures, as a reference displacement amount, a displacement amount of the horn during a reference period which is at least a partial period of a period from the state in which the one conductor and the other conductor superimposed via the synthetic resin are interposed by the horn and the anvil, through a first stable state in which a displacement speed of the horn is stable in a first speed zone in a course in which the displacement speed increases, until a second stable state in which the displacement speed is stable in a second speed zone of a higher speed zone than the first speed zone, and an adjustment element that adjusts ultrasonic vibration energy of the horn so that the ultrasonic vibration energy of the horn decreases continuously or step by step during a period following the reference period as the reference displacement amount measured by the measurement element increases.

### Advantageous Effects of Invention

The “first stable state” is a state in which the displacement speed of the horn is stable in the first speed zone and corresponds to a state before start of or an early stage of melting and removal of the synthetic resin between the both conductors by the ultrasonic vibration energy of the horn. The “second stable state” is a state in which the displacement speed of the horn is stable in the second speed zone of a higher speed zone than the first speed zone and is equivalent to an ending stage or a state after end of the melting and removal of the synthetic resin between the both conductors.

The displacement amount of the horn during the period from start of the displacement of the horn for the welding of the one conductor and the other conductor, through the first stable state in the course in which the displacement speed increases to the second stable state indicates a progress situation of the melting and removal of the synthetic resin between the both conductors. Therefore, when the magnitude of the ultrasonic vibration energy of the horn is controlled based on the magnitude of the displacement amount (the reference displacement amount) of the horn during at least a partial period (the reference period) of the period, the magnitude of energy converted to the welding of both conductors is appropriately adjusted from the viewpoint of realizing sufficient welding strength by the welding of the both conductors.

### BRIEF DESCRIPTION OF DRAWINGS

FIG. 1 is a diagram illustrating a configuration of an ultrasonic welding device according to an embodiment of the invention.

FIG. 2 is a diagram illustrating a change form of a displacement amount of a horn.

FIG. 3 is a diagram illustrating an ultrasonic welding method according to a first embodiment of the invention.

FIG. 4 is a diagram illustrating an ultrasonic welding method according to a second embodiment of the invention.

FIG. 5 is a diagram illustrating an ultrasonic welding method according to a third embodiment of the invention.

### DESCRIPTION OF EMBODIMENTS

(Configuration)

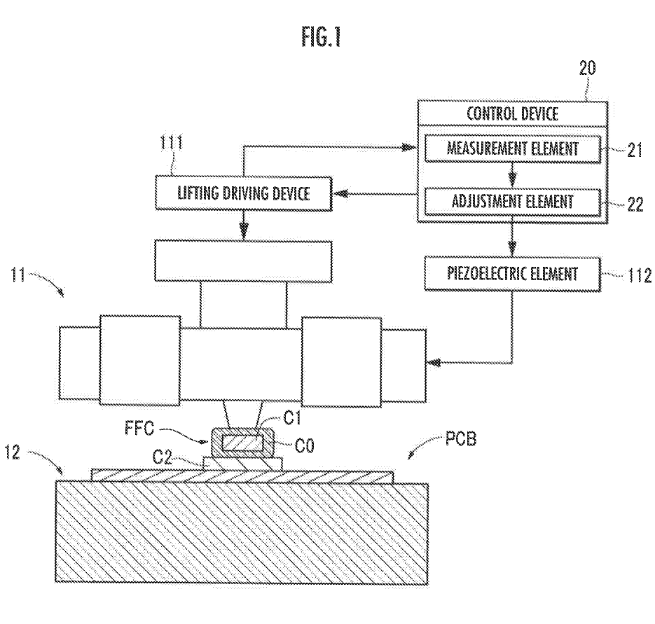

An ultrasonic welding device according to an embodiment of the invention, as illustrated in FIG. 1, includes a horn 11 (or a chip), an anvil 12 that is disposed below the horn 11 to face the horn 11, a lifting driving device 111 that drives the horn 11 in the vertical direction, a piezoelectric element 112 (an ultrasonic vibrator) that ultrasonically vibrates the horn 11, and a control device 20. A lower end portion of the horn 11 is formed so that an upper bottom surface is formed downward in a substantially truncated cone shape, but can be appropriately changed to, for example, a shape in which a front end of a conductor has a plurality of protrusions having belt-like or spotted front ends according to a disposition form of the conductor which is a welding target. The upper end portion of the anvil 12 is substantially planar, but an unevenness may be appropriately formed in accordance with the shape of the horn 11.

The control device 20 includes a computer (which includes an arithmetic processing unit (CPU), a memory (a storage device) such as a ROM or a RAM, an I/O circuit, and the like). The control device 20 controls an operation of each of the lifting driving device 111 and the piezoelectric element 112. The control device 20 includes a measurement element 21 and an adjustment element 22. The elements 21 and 22 each include an arithmetic processing unit that reads a program and data necessary from the storage device and performs an arithmetic process to be described below according to the program and the data.

As welding targets by the ultrasonic welding device, for example, a first conductor C1 (one conductor) formed of metal for a flexible flat cable (FFC) and a second conductor C2 (the other conductor) formed of metal for a printed circuit board (PCB) are adopted. The FFC includes an insulating coating C0 formed of a synthetic resin that covers the first conductor C1 in addition to the first conductor C1. The PBC includes a board supporting the second conductor C2.

Only the single first conductor C1 is illustrated to facilitate the drawings, but the plurality of first conductors C1 arranged in parallel in the horizontal direction and extending in the vertical direction in the FFC is covered with the insulating coating C0 so that the first conductors C1 are electrically isolated from each other. Similarly, only the single second conductor C2 is illustrated, but the plurality of second conductors C2 is installed on a board in the PCB.

In addition to the conductors included in the FFC and the PCB, conductors included in the plurality of FFCs or conductors included in the FFC and a flexible printed circuit (FPC) may be considered to be welding targets.

(Method of Adjusting Ultrasonic Energy (First Embodiment))

An ultrasonic welding method will be described as a first embodiment of the invention realized by the ultrasonic welding device that has the foregoing configuration. First, as illustrated in FIG. 1, the FFC and the PCB are interposed to be superimposed vertically between the horn 11 and the anvil 12. At this time, each of the first conductors C1 of the FFC and each of the second conductors C2 of the PCB are in a state of being vertically superposed with each other, with the insulating coating C0 of the FFC interposed therebetween.

From this state, the horn 11 is displaced to approach the anvil 12 by the lifting driving device 111, and thus by applying a load in the vertical direction to the FFC and the PCB and by applying an alternating-current voltage with a high frequency to the piezoelectric element 112 to ultrasonically vibrate the horn 11 (in the horizontal direction in the drawing), the FFC and the PCB (or the first conductor C1 and the second conductor C2) start to be welded.

(Time Change Form of Displacement Amount of Horn)

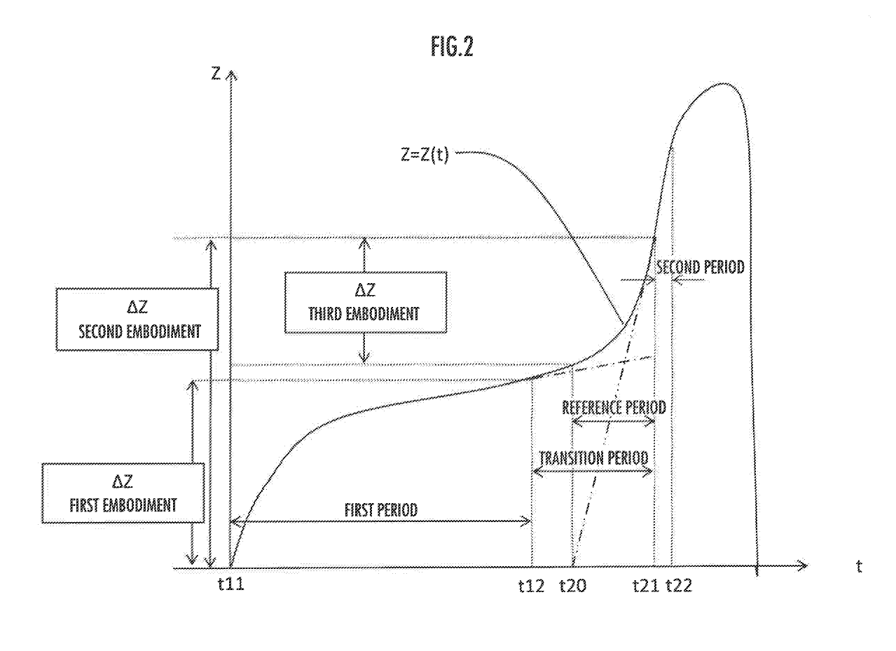

Until welding of the first conductor C1 and the second conductor C2 is completed, a displacement amount Z of the horn 11 is changed in accordance with a function Z(t) of a time t simplified in, for example, FIG. 2.

That is, the displacement amount Z of the horn 11 first increases at a relatively high speed during the early term of a first period [t₁₁, t₁₂], and subsequently increases at a relatively low speed. A “first stable state” in which a displacement speed v of the horn 11 is stable in a first speed zone during the late term (or the middle term and the late term) of the first period [t₁₁, t₁₂] is realized. The first speed zone is a speed zone that is defined by a lower limit and an upper limit of a slope of a curve line Z=Z(t) in the late term of the first period. A time change form of the displacement amount Z of the horn 11 during the first period [t₁₁, t₁₂] is in conformity with Relational Expression (1) below.

ε₁(t)=(σ₀/E){1−exp(−(t)/(η/E))} (1)

Relational Expression (1) approximately expresses a strain amount ε₁(t) (equivalent to the displacement amount Z of the horn 11) of the insulating coating C0 formed of a synthetic resin when a constant external force σ₀ is applied at time t=−0 in accordance with the Kelvin-Voigt model. In this model, elasticity and viscosity characteristics of the synthetic resin are expressed by a parallel spring (elastic coefficient: E) and a damper (attenuation coefficient: η).

In FIG. 2, a tangential line L1 of the curve line Z=Z(t) at an ending time point t=t₁₂ of the first stable state is indicated by a one-dot chain line. The slope of the tangential line is approximately (σ₀/η) according to Expression (1). The slope of the curve line Z=Z(t) during the first period approximately follows the tangential line L1. The “first stable state” is equivalent to an early stage of or a state before start of the melting and removal of the synthetic resin (the insulating coating C0) between the both conductors C1 and C2 by the ultrasonic vibration energy of the horn 11.

The temperature of the FFC and the PCB at spots interposed between the horn 11 and the anvil 12 are locally increased by the ultrasonic vibration energy of the horn 11, and the insulating coating C0 of the FFC is locally melted. The melted insulating coating C0 (the synthetic resin) is gradually removed from between the horn 11 and the anvil 12 because of a load of the horn 11 and the anvil 12 in the vertical direction. At this time, the insulating coating C0 between the first conductor C1 and the second conductor C2 is also melted and is gradually removed from between the first conductor C1 and the second conductor C2. As illustrated in FIG. 2, the speed v of the horn 11 gradually increases during the transition period [t₁₂, t₂₁].

Subsequently, the second conductor C2 abuts on the first conductor C1 while the second conductor C2 is plastically deformed. Frictional heat occurs in the abutting spots due to the ultrasonic vibration energy of the horn 11, an oxide film generated on the metal surface of each of the first conductor C1 and the second conductor C2 is removed, and an active surface (also referred to as a clean surface) is exposed to cause welding reaction (also referred to as solid phase welding).

When the solid phase welding reaction between the first conductor C1 and the second conductor C2 is in progress, a “second stable state” in which the displacement speed v of the horn 11 is stable in a second speed zone during the second period [t₂₁, t₂₂] is realized. The second speed zone is a speed zone that is defined by a lower limit and an upper limit of a slope of a curve line Z=Z(t) during the second period. A time change form of the displacement amount Z of the horn 11 during the second period [t₂₁, t₂₂] is consistent with Relational Expression (2) below.

ε₂(t)=A·D·(σ₀/G)ⁿ×t (2)

Relational Expression (2) approximately expresses a strain amount ε₂(t) in a transient creep region of the first conductor C1 and the second conductor C2 formed of metal using a material constant A, a diffusion coefficient D, and a coefficient G of the metal.

In FIG. 2, a tangential line L2 of the curve line Z=Z(t) at a starting time point t=t₂₁ of the second stable state is indicated by a two-dot chain line. The slope of the tangential line is approximately A·D·(σ₀/G)ⁿ according to Expression (2). The slope of the curve line Z=Z(t) during the second period approximately follows the tangential line L2. As apparent from the fact that the slope of the curve line Z=Z(t) is greater in the second period than in the first period, the second speed zone is a higher speed zone than the first speed zone. The “second stable state” is equivalent to an ending stage of or a state after end of the melting and removal of the synthetic resin (the insulating coating C0) between the both conductors C1 and C2.

(Method of Adjusting Ultrasonic Energy)

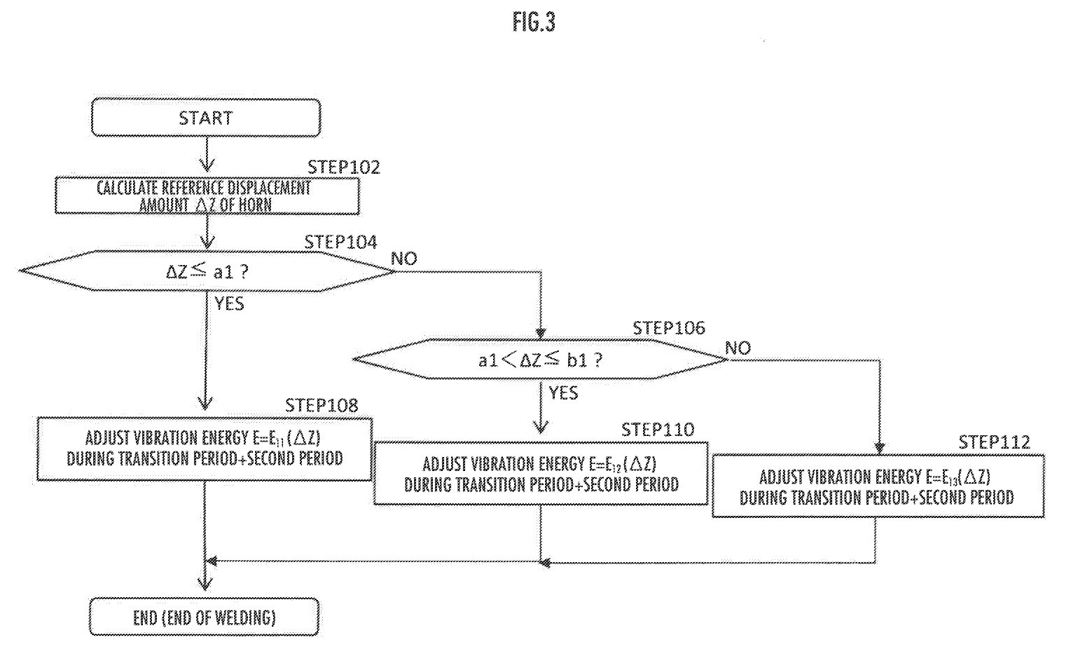

The measurement element 21 of the control device 20 measures a displacement amount Z (t₁₂)−Z(t₁₁) of the horn 11 during the “first period” serving as a “reference period” as a reference displacement amount ΔZ based on an output signal from a displacement amount sensor (not illustrated) according to the displacement amount Z of the horn 11 (STEP 102 of FIG. 3). For example, a time point at which the displacement speed v of the horn 11 exceeds the first speed zone is measured as an ending point t=t₁₂ of the first period. In addition to the welding starting time, a time point at which the displacement speed v of the horn 11 enters the first speed zone may be similarly measured as a starting time point t=t₁₁ of the first period.

It is determined whether the reference displacement amount ΔZ of the horn 11 is equal to or less than at (STEP 104 of FIG. 3). When the determination result is negative (NO in STEP 104 of FIG. 3), it is further determined whether the reference displacement amount ΔZ of the horn 11 exceeds at and is equal to or less than b₁(STEP 106 of FIG. 3). According to the determination results, the ultrasonic vibration energy E of the horn 11 during each of the transition period and the second period continuing from the transition period is controlled in the following way.

When the reference displacement amount ΔZ is determined to be equal to or less than at (YES in STEP 104 of FIG. 3), the ultrasonic vibration energy E of the horn 11 is controlled in accordance with a relational expression E=E₁₁(ΔZ) based on the reference displacement amount ΔZ (STEP 108 of FIG. 3). When the reference displacement amount ΔZ is determined to exceed a₁ and be equal to or less than b₁ (YES in STEP 106 of FIG. 3), the ultrasonic vibration energy E of the horn 11 is controlled in accordance with a relational expression E=E₁₂ (ΔZ) based on the reference displacement amount ΔZ (STEP 110 of FIG. 3). When the reference displacement amount ΔZ is determined to be equal to or greater than b₁ (NO in STEP 106 of FIG. 3), the ultrasonic vibration energy E of the horn 11 is controlled in accordance with a relational expression E=E₁₃ (ΔZ) based on the reference displacement amount ΔZ (STEP 112 of FIG. 3). A relation of E₁₁>E₁₂>E₁₃ is satisfied among E₁₁, E₁₂, and E₁₃.

Then, after the welding reaction between the first conductor C1 and the second conductor C2 is completed, the horn 11 returns to the original position and the ultrasonic vibration is also stopped.

(Ultrasonic Welding Method (Second Embodiment))

An ultrasonic welding method will be described as a second embodiment of the invention realized by the ultrasonic welding device that has the foregoing configuration. Since the second embodiment is common to the first embodiment except for a method of controlling ultrasonic vibration energy, the common factors will not be described.

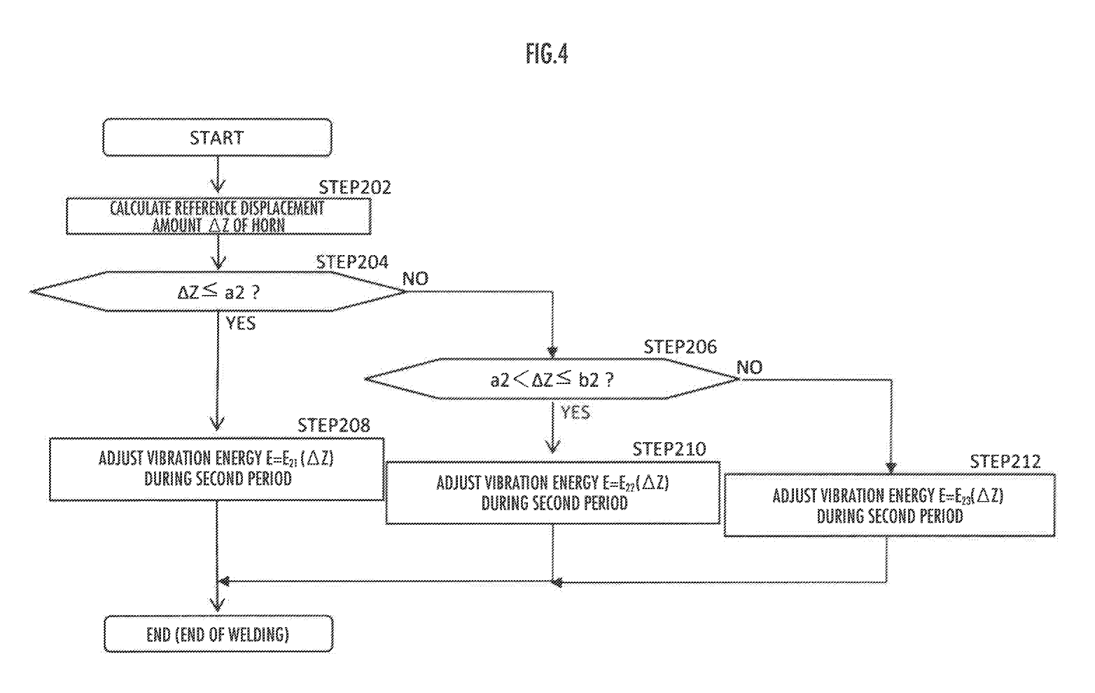

A displacement amount Z(t₂₁)−Z(t₁₁) of the horn 11 during a “first period” serving as a “reference period” and a “transition period” is measured as a reference displacement amount ΔZ (STEP 202 of FIG. 4). For example, a time point at which the displacement speed v of the horn 11 enters the second speed zone may be measured as an ending point (a starting point of the second period) t=t₂₁ of the transition period.

It is determined whether the reference displacement amount ΔZ of the horn 11 is equal to or less than a₂ (STEP 204 of FIG. 4). When the determination result is negative (NO in STEP 204 of FIG. 4), it is further determined whether the reference displacement amount ΔZ of the horn 11 exceeds a₂ and is equal to or less than b₂ (STEP 206 of FIG. 4). According to the determination results, the ultrasonic vibration energy E of the horn 11 during each of the transition period and the second period continuing from the transition period is controlled in the following way.

When the reference displacement amount ΔZ is determined to be equal to or less than a₂ (YES in STEP 204 of FIG. 4), the ultrasonic vibration energy E of the horn 11 is controlled in accordance with a relational expression E=E₂₁ (ΔZ) based on the reference displacement amount ΔZ (STEP 208 of FIG. 4). When the reference displacement amount ΔZ is determined to exceed a₂ and be equal to or less than b₂ (YES in STEP 206 of FIG. 4), the ultrasonic vibration energy E of the horn 11 is controlled in accordance with a relational expression E=E₂₂ (ΔZ) based on the reference displacement amount ΔZ (STEP 210 of FIG. 4). When the reference displacement amount ΔZ is determined to be equal to or greater than b₂ (NO in STEP 206 of FIG. 4), the ultrasonic vibration energy E of the horn 11 is controlled in accordance with a relational expression E=E₂₃ (ΔZ) based on the reference displacement amount ΔZ (STEP 212 of FIG. 4). A relation of E₂₁>E₂₂>E₂₃ is satisfied among E₂₁, E₂₂, and E₂₃.

Then, after the welding reaction between the first conductor C1 and the second conductor C2 is completed, the horn 11 returns to the original position and the ultrasonic vibration is also stopped.

(Ultrasonic Welding Method (Third Embodiment))

An ultrasonic welding method will be described as a third embodiment of the invention realized by the ultrasonic welding device that has the foregoing configuration. Since the third embodiment is common to the first embodiment except for a method of controlling ultrasonic vibration energy, the common factors will not be described.

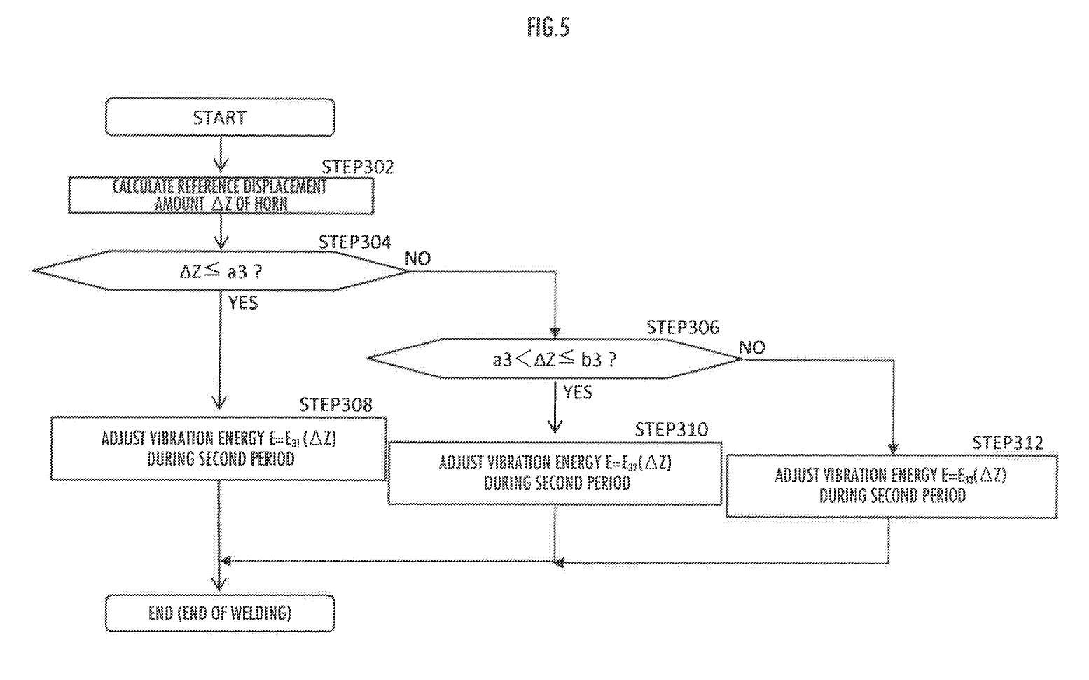

A displacement amount of the horn 11 during a “reference period” is measured as a reference displacement amount ΔZ (STEP 302 of FIG. 5). Specifically, a time point t=t₂₀ equivalent to an intersection between a time axis and a tangential line L2 of a curve line Z=f(t) at an ending time point t=t₂₁ (a starting time point of the second stable state) of a transition period [t₁₂, t₂₁] from the first stable state to the second stable state is obtained. A period [t₂₀, t₂₁] in which the time point t=t₂₀ is a starting time point and a starting time point t=t₂₁ of the second stable state is an ending time point is set as the reference period.

It is determined whether the reference displacement amount ΔZ of the horn 11 is equal to or less than a₃ (STEP 304 of FIG. 5). When the determination result is negative (NO in STEP 304 of FIG. 5), it is further determined whether the reference displacement amount ΔZ of the horn 11 exceeds a₃ and is equal to or less than b₃ (STEP 306 of FIG. 5). According to the determination results, the ultrasonic vibration energy E of the horn 11 during the second period is controlled in the following way.

When the reference displacement amount ΔZ is determined to be equal to or less than a₃ (YES in STEP 304 of FIG. 5), the ultrasonic vibration energy E of the horn 11 is controlled in accordance with a relational expression E=E₃₁ (ΔZ) based on the reference displacement amount ΔZ (STEP 308 of FIG. 5). When the reference displacement amount ΔZ is determined to exceed a₃ and be equal to or less than b₃ (YES in STEP 306 of FIG. 5), the ultrasonic vibration energy E of the horn 11 is controlled in accordance with a relational expression E=E₃₂ (ΔZ) based on the reference displacement amount ΔZ (STEP 310 of FIG. 5). When the reference displacement amount ΔZ is determined to be equal to or greater than b₃ (NO in STEP 306 of FIG. 5), the ultrasonic vibration energy E of the horn 11 is controlled in accordance with a relational expression E=E₃₃ (ΔZ) based on the reference displacement amount ΔZ (STEP 312 of FIG. 5). A relation of E₃₁>E₃₂>E₃₃ is satisfied among E₃₁, E₃₂, and E₃₃.

Then, after the welding reaction between the first conductor C1 and the second conductor C2 is completed, the horn 11 returns to the original position and the ultrasonic vibration is also stopped.

### Advantageous Effects

A displacement amount of the horn during a period from the state in which the FFC and the PCB are vertically interposed between the horn 11 and the anvil 12 through the first stable state in which the displacement speed v of the horn 11 increases (a state in which a displacement acceleration α=dv/dt=d²Z/dt² is equal to or greater than 0) to the second stable state indicates a progress situation of melting and removal of the synthetic resin included in the insulating coating C0 between the both conductors C1 and C2. The fact that the displacement amount (the reference displacement amount ΔZ) of the horn 11 during at least a partial period (reference period) of the period is large suggests that elasticity and viscosity of the synthetic resin included in the insulating coating C0 during the period is low or the temperature is high and thus the ultrasonic vibration energy E of the horn 11 is relatively high.

Therefore, by performing control such that the ultrasonic vibration energy E of the horn 11 is relatively low when the reference displacement amount ΔZ is large, the excessive ultrasonic vibration energy E at the time of welding the both conductors C1 and C2 is prevented. Therefore, it is possible to reliably realize sufficient welding strength between the conductors C1 and C2. In contrast, by performing control such that the ultrasonic vibration energy E of the horn 11 is relatively high when the reference displacement amount ΔZ is small, the small ultrasonic vibration energy E at the time of welding the both conductors C1 and C2 is prevented. Therefore, it is possible to reliably realize sufficient welding strength between the conductors C1 and C2.

### Other Embodiments of Invention

In the first to third embodiments, the ultrasonic vibration energy E is adjusted at three stages according to the magnitude of the reference displacement amount ΔZ. However, in another embodiment, the ultrasonic vibration energy E may be adjusted at two stages or at multiple stages equal to or greater than four stages according to the magnitude of the reference displacement amount ΔZ or may be adjusted continuously.

As the reference period, a period of another form such as, for example, a period [t₁₁, t₂₀] or a period [t₁₂, t₂₀] may be adopted as long as the reference period is at least a partial period of a period from a displacement starting time t=t₁₁ of the horn 11 to an ending time t=t₂₁ of the transition period from the first stable state to the second stable state.

In the first to third embodiments, the reference period may be set to start after the displacement amount Z from the displacement starting time t=t₁₁ of the horn 11 reaches a predetermined amount Z₀. In this case, the reference displacement amount ΔZ in each of the first to third embodiments may be substituted with ΔZ−Z₀ and the ultrasonic vibration energy E may be adjusted according to the magnitude of the reference displacement amount after the substitution, as described above.

### DESCRIPTION OF REFERENCE NUMERALS

11 horn
12 anvil
111 lifting driving device
112 piezoelectric element (ultrasonic vibrator)
20 control device
21 measurement element
22 adjustment element
C1 first conductor (one conductor)
C2 second conductor (the other conductor)
R insulating coating (synthetic resin)

1. An ultrasonic welding device comprising:
a horn that is vibrated by a piezoelectric element;
an anvil that is disposed to face the horn; and
a control device,
wherein a synthetic resin is melted to be removed from between one conductor and another conductor by displacing the horn in a superimposing direction of the one conductor and the other conductor while ultrasonically vibrating the horn in a state in which the one conductor and the other conductor superimposed via the synthetic resin are interposed by the horn and the anvil, and the one conductor and the other conductor are welded, and
wherein the control device includes
a measurement element that measures, as a reference displacement amount, a displacement amount of the horn during a reference period which is at least a partial period of a period from the state in which the one conductor and the other conductor superimposed via the synthetic resin are interposed by the horn and the anvil, through a first stable state in which a displacement speed of the horn is stable in a first speed zone in a course in which the displacement speed increases, until a second stable state in which the displacement speed is stable in a second speed zone of a higher speed zone than the first speed zone, and
an adjustment element that adjusts ultrasonic vibration energy of the horn so that the ultrasonic vibration energy of the horn decreases continuously or step by step during a period following the reference period as the reference displacement amount measured by the measurement element increases.

2. The ultrasonic welding device according to claim 1,
wherein the measurement element measures the reference displacement amount using a period from the state in which the one conductor and the other conductor superimposed via the synthetic resin are interposed by the horn and the anvil until the first stable state ends, as the reference period.

3. The ultrasonic welding device according to claim 1,
wherein the measurement element measures the reference displacement amount using a period from the state in which the one conductor and the other conductor superimposed via the synthetic resin are interposed by the horn and the anvil until a transition period from the first stable state to the second stable state ends, as the reference period.

4. The ultrasonic welding device according to claim 1,
wherein the measurement element measures the reference displacement amount using a partial period including at least an ending point in a transition period from the first stable state to the second stable state, as the reference period.

5. The ultrasonic welding device according to claim 4,
wherein the measurement element sets the reference period using, as a starting time point, a time point corresponding to an intersection between a time axis and a tangential line at an ending time point of the transition period in a curve line indicating a time change form of the displacement amount of the horn on a two dimensional coordinate system on which a time and the displacement amount of the horn are coordinate values.

6. An ultrasonic welding method of melting a synthetic resin to remove the synthetic resin from between one conductor and another conductor by displacing a horn vibrated by a piezoelectric element in a superimposing direction of the one conductor and the other conductor while ultrasonically vibrating the horn in a state in which the one conductor and the other conductor superimposed via the synthetic resin are interposed by the horn and an anvil disposed to face the horn, and welding the one conductor and the other conductor, the method comprising:
a measurement step of measuring, as a reference displacement amount, a displacement amount of the horn during a reference period which is at least a partial period of a period from the state in which the one conductor and the other conductor superimposed via the synthetic resin are interposed by the horn and the anvil, through a first stable state in which a displacement speed of the horn is stable in a first speed zone in a course in which the displacement speed increases, until a second stable state in which the displacement speed is stable in a second speed zone of a higher speed zone than the first speed zone; and
an adjustment step of adjusting ultrasonic vibration energy of the horn so that the ultrasonic vibration energy of the horn decreases continuously or step by step during a period following the reference period as the reference displacement amount measured in the measurement step increases.
